(19) United States
(12) Patent Application Publication
(10) Pub. No.: US 2013/0328451 A1
(43) Pub. Date: Dec. 12, 2013

(54) DIELECTRIC ELEMENT BASE MATERIAL, METHOD FOR PRODUCING SAME, AND PIEZOELECTRIC ELEMENT USING SAID DIELECTRIC ELEMENT BASE MATERIAL

(71) Applicants: Takashi Kubo, Osaka (JP); Toshinari Noda, Osaka (JP)

(72) Inventors: Takashi Kubo, Osaka (JP); Toshinari Noda, Osaka (JP)

(73) Assignee: PANASONIC CORPORATION, Kadoma-shi, Osaka (JP)

(21) Appl. No.: 14/000,825

(22) PCT Filed: Apr. 16, 2012
(86) PCT No.: PCT/JP2012/002615

§ 371 Date: Aug. 21, 2013

(30) Foreign Application Priority Data
Apr. 21, 2011 (JP) 2011-094603

(51) Int. Cl. H01L 41/08

(52) U.S. Cl. CPC H01L 41/081
USPC 310/348; 174/268

(57) ABSTRACT

A dielectric element substrate includes a board, a diffusion layer, a first isolation layer, and a lower electrode layer. The diffusion layer is provided on the board. The first isolation layer is provided on and unitarily with the diffusion layer. The lower electrode layer is provided on the first isolation layer at an opposite side with respect to the diffusion layer of, and is isolated from the diffusion layer by the first isolation layer. The diffusion layer is formed by allowing a first metal element and a second metal element to diffuse from the board to the same composition material as that of the first isolation layer. The first isolation layer is free from the first and second metal elements. A coefficient of thermal expansion of the diffusion layer decreases monotonously from the board to the first isolation layer.

### TECHNICAL FIELD

The present invention relates to a piezoelectric element having an electromechanical transducing function, a dielectric element substrate used for the piezoelectric element, and a method for producing the substrate.

### BACKGROUND ART

Recently, MEMS (Micro Electro Mechanical Systems) devices represented by micromachines have been widely mounted on AV apparatuses, automobiles, or the like, and are indispensable for achieving comfort, safety, and feeling of security. The MEMS devices, for example, angular velocity sensors necessary for vehicle attitude control and correcting camera shake in digital camera, a printer head of an inkjet printer, projection engine for a projector, and the like, have been applied in our surrounding. One of component technologies essential to such devices is a piezoelectric thin film. The piezoelectric thin film is a material which generates an electric charge when a force is applied, and on the contrary, which generates distortion when an electric field is applied.

Typical examples of piezoelectric thin film material include lead zirconate titanate (hereinafter, which is referred to as “PZT”) thin film having an excellent piezoelectric property. PZT is a solid solution of PbZrO₃ and PbTiO₃ both having a perovskite structure, and is represented by general formula: Pb(Zr, Ti₁₋ₓ)O₃ (0<x<1). When Zr in PbZrO₃ is being substituted with Ti, a crystal system transits from a rhombohedral system to a tetragonal system in the vicinity of Zr/Ti=53/47. This phase boundary is referred to as a morphotropic phase boundary. It is known that a physical constant such as a relative dielectric constant and a piezoelectric constant shows a local maximum in the vicinity of the phase boundary.

Furthermore, the PZT thin film has different physical constants depending upon the orientation direction. That is to say, the PZT thin film has an anisotropic property with respect to the generation of distortion by the application of an electric field, and distortion becomes larger when an electric field is applied in the axial direction referred to as the polarization axis. In a tetragonal PZT thin film, a C-axial direction ((001) direction) that is a longitudinal axis of the crystal lattice is a polarization axis. When directions of the crystal lattices are aligned to this direction (referred to as orientation control), a high piezoelectric constant is shown. Furthermore, the linearity of the piezoelectric constant (a proportional property of displacement magnitude with respect to the applied electric field) is excellent.

Examples of production methods of the PZT thin film include vapor growth methods such as a vapor deposition method, a sputtering method, and a CVD (Chemical Vapor Deposition) method, or liquid phase growth methods represented by a CSD (Chemical Solution Deposition) method. Among them, the CSD method can be carried out at a low cost because it is a non-vacuum process. Furthermore, the composition can be controlled easily by preparing a precursor solution that is homogeneous at a molecular level, and in-plane homogeneity (composition and film thickness) can be enhanced by applying a spin coating method. Therefore, characteristics such as reproducibility, applicability for film formation with respect to a large-area board, or the like, can be achieved.

When consistency with the semiconductor process is taken into account, the PZT thin film is usually formed on a Si board provided with a lower electrode layer of Pt (111). However, since the PZT thin film is oriented in a (111) direction on the lower electrode layer of Pt (111), an orientation control layer for controlling the orientation of the PZT thin film is formed on the lower electrode layer of Pt (111). As the orientation control layer, a LaNiO₃ (hereinafter, referred to as “LNO”) thin film that has an excellent lattice matching with respect to a (001) plane of PZT, or the like, is considered. Furthermore, since the LNO thin film is a perovskite type electric conductive oxide, it functions as an electrode. When such a LNO thin film is used as an orientation control layer and a lower electrode layer, the PZT thin film having excellent crystal orientation can be formed on various boards other than the board of a single crystal such as Si.

Note here that prior art literatures related to the present invention include Patent Literature 1.

### CITATION LIST

### Patent Literature

Patent Literature 1: Japanese Patent No. 3127245

### SUMMARY OF THE INVENTION

The present invention has an object to provide a dielectric element substrate which is free from composition displacement and shows less warpage when a piezoelectric layer or a lower electrode layer is formed, and a piezoelectric element using the piezoelectric layer. A dielectric element substrate of the present invention includes a board, a diffusion layer, a first isolation layer, and a lower electrode layer. The board includes a first metal element and a second metal element. The diffusion layer is provided on the board, and the first isolation layer is provided on and unitarily with the diffusion layer. The lower electrode layer is provided on the first isolation layer at an opposite side with respect to the diffusion layer, and is isolated from the diffusion layer by the first isolation layer. The diffusion layer is formed by allowing a first metal element and a second metal element to diffuse from the board to the same composition material as that of the first isolation layer. The first isolation layer is free from the first and second metal elements. A coefficient of thermal expansion of the diffusion layer monotonously decreases from the board to the first isolation layer. Furthermore, the piezoelectric element of the present invention includes the above-mentioned dielectric element substrate, a piezoelectric layer provided on the lower electrode layer, and an upper electrode layer provided on the piezoelectric layer.

By monotonously reducing the coefficient of thermal expansion from the board to the first isolation layer, a thermal stress from the board can be relaxed. Therefore, warpage of the board can be reduced. At the same time, it is possible to suppress diffusion of the metal elements included in the board into the lower electrode layer.

### BRIEF DESCRIPTION OF THE DRAWINGS

FIG. 1 is a sectional view showing one structural example of a piezoelectric element in accordance with a first exemplary embodiment of the present invention.

FIG. 2 is a graph showing an X-ray diffraction pattern of a piezoelectric layer in a range in which 2θ is 10° or more and 60° or less in accordance with the first exemplary embodiment of the present invention.

FIG. 3 is a graph showing an X-ray diffraction pattern of the piezoelectric layer in a range in which 2θ is 93° or more and 103° or less in accordance with the first exemplary embodiment of the present invention.

FIG. 4 is a graph showing elemental analysis results in the depth direction of the piezoelectric element in accordance with the first exemplary embodiment of the present invention.

FIG. 5 is a sectional view showing one structural example of a piezoelectric element in accordance with a second exemplary embodiment of the present invention.

### DETAILED DESCRIPTION OF THE PREFERRED EMBODIMENT

In a conventional configuration in which a LNO thin film as a lower electrode layer is formed directly on the board, elements included in the board easily diffuse into the lower electrode layer and a piezoelectric layer. As a result, a composition of the piezoelectric layer is changed or displaced from the original one, which may deteriorate characteristics of a piezoelectric element. Furthermore, when a diffusion prevention layer is formed between the board and the lower electrode layer, the board may be warped due to a difference in coefficient of thermal expansion between the board and the diffusion prevention layer at a temperature change.

In the following exemplary embodiments, a dielectric element substrate which solves the above-mentioned problem and the piezoelectric element using thereof are described.

### First Exemplary Embodiment

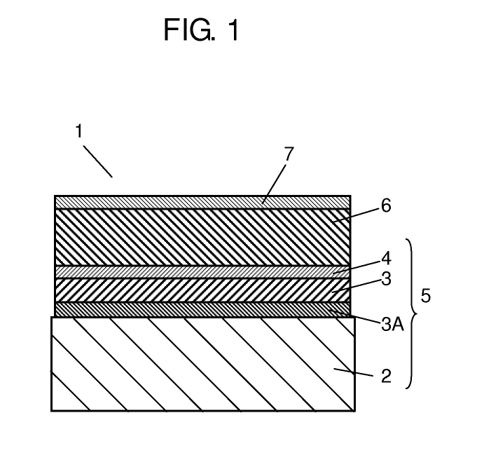

FIG. 1 is a sectional view showing one structural example of a piezoelectric element in accordance with a first exemplary embodiment of the present invention. Piezoelectric element 1 includes dielectric element substrate 5, and piezoelectric layer 6 and upper electrode layer 7 which are sequentially laminated on a principal surface of dielectric element substrate 5. Dielectric element substrate 5 includes board 2 having a pair of opposite principal surfaces, and diffusion layer 3A, first isolation layer 3, and lower electrode layer 4 which are sequentially laminated on at least one of the principal surfaces of board 2. That is to say, piezoelectric layer 6 is laminated on lower electrode layer 4.

As described above, dielectric element substrate 5 includes board 2, diffusion layer 3A, first isolation layer 3, and lower electrode layer 4. Diffusion layer 3A is provided on board 2, and first isolation layer 3 is provided on diffusion layer 3A. Lower electrode layer 4 is provided on first isolation layer 3 at an opposite side with respect to diffusion layer 3A.

Board 2 includes a first metal element and a second metal element. For example, stainless steel including iron as the first metal element and chromium as the second metal element can be used as board 2. Diffusion layer 3A is formed by allowing the first metal element and the second metal element to diffuse from board 2 to the same composition material as that for first isolation layer 3. On the other hand, first isolation layer 3 is free from the first metal element and the second metal element. Since diffusion layer 3A is formed by allowing the first metal element and the second metal element to diffuse to a board 2 side of a single layer forming first isolation layer 3 in this way, it is provided unitarily with first isolation layer 3. Diffusion layer 3A is provided in a layer structure at a boundary with respect to board 2, and covers a part or an entire part of the principal surface of board 2. Furthermore, first isolation layer 3 isolates diffusion layer 3A from lower electrode layer 4.

A concentration gradient of the first metal element and a concentration gradient of the second metal element in diffusion layer 3A are different in the direction from board 2 to first isolation layer 3. Therefore, a coefficient of thermal expansion of diffusion layer 3A monotonously decreases from board 2 to first isolation layer 3.

Hereinafter, material of each component element is described in detail. As material of board 2, material having a larger coefficient of thermal expansion than that of piezoelectric layer 6 is selected. That is to say, for board 2, stainless steel including iron and chromium as a main component, special steel or alloy including nickel, cobalt, molybdenum, or the like, can be used. The following is description of an example in which stainless steel including iron and chromium as board 2 is used.

First isolation layer 3 insulates board 2 from lower electrode layer 4, and prevents metal elements diffusing in diffusion layer 3A from reaching lower electrode layer 4. Therefore, first isolation layer 3 is made of insulating material. For example, first isolation layer 3 is made of material including silicon oxide as a main component. In this exemplary embodiment, silicon oxide (SiOₓ: 0<x≦2) is used as first isolation layer 3, but, for example, a silicon nitride film (SiON) obtained by nitriding silicon oxide may be used.

Diffusion layer 3A is formed by allowing at least two types of metal elements included in board 2 to diffuse to material that is the same as that of first isolation layer 3. These elements have a concentration gradient reducing from the board 2 side to a first isolation layer 3 side. When stainless steel is used as board 2, elements diffusing into diffusion layer 3A are iron and chromium. The coefficient of thermal expansion is larger in iron than in chromium.

On the other hand, contrarily, an ionization tendency is greater in chromium than in iron. Consequently, in diffusion layer 3A, diffusion amounts of iron and chromium are different from each other due to a difference in the ionization tendency, and thus a diffusion amount of chromium becomes larger. Consequently, the ratio of iron is larger at the board 2 side, and the ratio of chromium becomes larger toward the first isolation layer 3 side. That is to say, in the direction from board 2 to first isolation layer 3, a diffusion length of chromium is greater than that of iron. As a result, the coefficient of thermal expansion is large at the board 2 side, and the coefficient of thermal expansion becomes smaller toward the first isolation layer 3 side.

When combinations of other elements are selected, as mentioned above, they may be selected with the coefficient of thermal expansion and the ionization tendency taken into consideration. That is to say, the same effect can be obtained by combining an element having a relatively large coefficient of thermal expansion and small ionization tendency, and an element contrarily having a small coefficient of thermal expansion and large ionization tendency.

Lower electrode layer 4 is formed of material including LNO as a main component. LNO has a space group of R3c, and has a perovskite structure distorted into a rhombohedral shape. Specifically, in the rhombohedral system, a₀=5.461 Å (a₀=ap) and α=60° are satisfied. In the pseudocubic crystal system, a₀=3.84 Å is satisfied. The resistivity of LNO at 300K is 1×10⁻³ (Ω·cm). As described above, LNO is oxide having metallic electrical conductivity, and transition from metal into insulator doesn't occur even when a temperature is changed.

The material including LNO as a main component also includes material in which a part of nickel is substituted with the other metal. Examples of the above-mentioned other metal include at least one metal selected from the group consisting of iron, aluminum, manganese, and cobalt. Examples include LaNiO₃—LaFeO₃, LaNiO₃—LaAlO₃, LaNiO₃—LaMnO₃, LaNiO₃—LaCoO₃, or the like. Furthermore, if necessary, material in which the part is substituted with two or more metals may be used.

Piezoelectric layer 6 is formed of PZT in a (001) plane orientation of a rhombohedral system or a tetragonal system. A composition of PZT is a composition in the vicinity of the phase boundary between the tetragonal system and the rhombohedral system (morphotropic phase boundary). For example, Zr/Ti=53/47 is satisfied. The composition of PZT is not necessarily limited to Zr/Ti=53/47, but it may be any composition satisfying 30/70≦Zr/Ti≦70/30. Furthermore, component material of piezoelectric layer 6 is not necessarily limited to PZT, but it includes material including PZT as a main component and a small amount of at least one metal selected from the group consisting of Sr, Nb, and Al.

For upper electrode layer 7, any conductive material such as metal and alloy, electroconductive metal oxide can be used without limitation. Typically, gold is used.

Next, a method for producing dielectric element substrate 5 is described. Firstly, an intermediate layer which is a base material layer of diffusion layer 3A and first isolation layer 3 is formed on board 2. In order to do so, for example, a precursor solution for forming the intermediate layer is coated by a spin coating method for forming a precursor film. When silicon oxide is formed as the intermediate layer, a solution including tetraethoxysilane (Si(OC₂H₅)₄) as a main component is used as the precursor solution. Other than this solution, a precursor solution including methyltriethoxysilane (CH₃Si(OC₂H₅), perhydropolysilazane (SiH₂NH), or the like, as a main component may be used. Such a silicon oxide precursor solution is coated on the principal surface of board 2 by the spin coating method. The spin coating is carried out under conditions of a rotational speed of 2500 rpm for 30 seconds.

Thereafter, heating is carried out at, for example, 150° C. for 10 minutes so as to dry the coated film. With this operation, physically adsorbed water content in the coated film (the precursor film) is removed. At this time, the temperature is desirably higher than 100° C. and lower than 200° C. When the temperature is 200° C. or higher, residual organic constituents remaining in the precursor film begins decomposing, and when the decomposition occurs in concurrence with removal of the water content, the resultant film becomes rough. Furthermore, in order to prevent the water content from remaining in the produced intermediate layer, drying is preferably carried out at a temperature of higher than 100° C. Subsequently, heating is carried out at 500° C. for 10 minutes, a residual organic substance is thermally decomposed to increase the density of the film.

A series of operations including coating the precursor solution on board 2, drying thereof, and increasing the density is repeated a plurality of times so that a predetermined thickness is obtained, and thus the intermediate layer is formed. Herein, when thermal treatment is carried out at 500° C., iron and chromium, which are constituent elements of board 2, are allowed to diffuse into the intermediate layer to so as form diffusion layer 3A. At that time, by using a difference in ionization tendency between iron and chromium, concentration gradients of iron and chromium are formed in diffusion layer 3A. That is to say, since the ionization tendency of chromium is higher as compared with iron, chromium diffuses to the relatively upper portion of the intermediate layer. When coefficients of thermal expansion of iron and chromium are compared with each other, the coefficient of thermal expansion of iron is larger, so that diffusion layer 3A that is a region in which the coefficient of thermal expansion is monotonously reduced from board 2 to first isolation layer 3 is formed.

Note here that in the above description, a silicon oxide layer as the intermediate layer is formed by the CSD method, but the production method is not necessarily limited to the CSD method. Diffusion layer 3A can be formed by any methods as long as the method includes forming a precursor thin film on board 2 and increasing the density of material that constitutes the intermediate layer by heating.

The film thickness of the intermediate layer is desirably 0.20 μm or more, and desirably 0.95 μm or less. When the film thickness is less than 0.20 μm, iron and chromium which are constituent elements of board 2 diffuse into the entire part of the intermediate layer, so that the entire part of the intermediate layer may become diffusion layer 3A. In this case, chromium, or chromium and iron reach lower electrode layer 4. When iron or chromium diffuses into lower electrode layer 4, a crystallinity of LNO is deteriorated. Note here that in order to reliably prevent iron or chromium from reaching lower electrode layer 4, it is further preferable that the film thickness of the intermediate layer is 0.30 μm or more. On the other hand, when the film thickness is larger than 0.95 μm or more, cracking, chipping, microcracks, or the like, may occur in the intermediate layer.

Next, lower electrode layer 4 is formed on the intermediate layer. Hereinafter, one example of a method for forming lower electrode layer 4 with LNO by using the CSD method is described.

As starting material for a LNO precursor solution, lanthanum nitrate hexahydrate (La(NO₃)₃.6H₂O) and nickel acetate tetrahydrate (CH₃COO)₂Ni.4H₂O) are used. As a solvent, 2-methoxyethanol and 2-aminoethanol can be used. Since 2-methoxyethanol includes a slight amount of water content, it is desirable that the water content is previously removed by using molecular sieves having an average hole diameter of 0.3 nm.

Firstly, lanthanum nitrate hexahydrate is made to be anhydrous by heating, then 2-methoxyethanol is added thereto, and stirred at room temperature so as to dissolve lanthanum nitrate. Thus, solution A is prepared. On the other hand, nickel acetate tetrahydrate is made to be anhydrous by heating, and then 2-methoxyethanol and 2-aminoethanol are added thereto, followed by refluxing. Thus, a nickel precursor solution (solution B) is produced. Solution A and solution B are mixed with each other and stirred, thus preparing a LNO precursor solution.

Next, the LNO precursor solution is coated on the intermediate layer by using the spin coating method to form a LNO precursor film. The coating is carried out under conditions of a rotational speed of 3500 rpm for 30 seconds. Thereafter, the LNO precursor film coated on the intermediate layer is heated and dried at, for example, 150° C. for 10 minutes. Drying conditions are the same as those for the coated film when the intermediate layer is formed. That is to say, it is desirable that the drying temperature is more than 100° C. and less than 200° C. Thereafter, a residual organic substance is thermally decomposed by heating at, for example, 350° C. for 10 minutes. The temperature at the time of thermal decomposition is desirably 200° C. or higher and lower than 500° C. When the temperature is 500° C. or higher, crystallization of the dried LNO precursor film largely proceeds. On the other hand, when the temperature is lower than 200° C., an organic constituent may remain in the produced LNO lower electrode layer.

The above-described procedure including coating LNO precursor solution on the intermediate layer, drying, and thermal decomposition is repeated a plurality of times such that the thickness of the LNO precursor film becomes a predetermined value. Thereafter, the intermediate product is rapidly heated by using a Rapid Thermal Annealing furnace (hereinafter, referred to as an “RTA furnace”), and then cooled so as to crystallize the LNO precursor film. The LNO precursor film crystallized under conditions of a temperature of 700° C. for 5 minutes and at a heating rate of 200° C./min. Note here that the crystallization temperature is desirably 500° C. or higher and 750° C. or lower. Through the above-mentioned procedures, lower electrode layer 4 having a thickness of 200 nm and which is formed of LNO that has been highly oriented in a (100) plane direction. Note here that lower electrode layer 4 formed of LNO may be produced by various well-known film formation methods including vapor growth methods such as a vapor deposition method, a hydrothermal method, or the like.

Next, a method for forming piezoelectric element 1 by using dielectric element substrate 5 is described. As the starting material for PZT for piezoelectric layer 6, lead (II) acetate trihydrate (Pb(OCOCH₃)₂.3H₂O), isopropoxide titanium (Ti(OCH(CH₃)₂)₄), and zirconium n-propoxide (Zr(OCH₂CH₂CH₃)₄) are used. As the solvent, ethanol is used. In order to prevent hydrolysis of metalalkoxide by contained water, it is desirable that previously dehydrated ethanol is used.

Firstly, lead (II) acetate trihydrate is made anhydrous by heating, and then dehydrated ethanol is added, followed by refluxing. Thus, a Pb precursor solution is prepared.

On the other hand, titanium isopropoxide and zirconium n-propoxide are mixed with each other, dehydrated ethanol is added and dissolved, and then the resultant product is refluxed at 78° C. for four hours. Thus, a Ti—Zr precursor solution is prepared. The Zr/Ti ratio is weighed so that, for example, the molar ratio satisfies Ti/Zr=47/53. The Ti—Zr precursor solution is mixed into the Pb precursor solution. At this time, a Pb component is allowed to be excessive by 20 mol % with respect to the stoichiometric composition (Pb(Zr_{0.53}, Ti_{0.47})O₃). With adjustment to this composition, a shortage of a lead component due to volatilization of the lead component at the time of crystallization annealing is compensated. The mixture solution is refluxed at 78° C. for four hours, acetylacetone as a stabilizing agent is added in 0.5 mol equivalent amount with respect to the total amount of a positive metallic ion, and then refluxed at 78° C. for one hour. Thus, a PZT precursor solution is prepared.

Next, the PZT precursor solution is coated on lower electrode layer 4 by the spin coating method. The coating is carried out under conditions of a rotational speed of 2500 rpm for 30 seconds. Thereafter, a PZT precursor film coated on lower electrode layer 4 is dried by heating, for example, at 115° C. for 10 minutes. The drying conditions may be the same as those for the coated film when the intermediate layer is formed. Thereafter, heating is carried out at 350° C. for 10 minutes, so that residual organic components are thermally decomposed. Preferable ranges of the drying temperature and the thermal decomposition temperature are the same as in the case where a LNO precursor film is formed. That is to say, it is desirable that the drying temperature is higher than 100° C. and less than 200° C. The temperature for thermal decomposition is desirably 200° C. or higher and less than 500° C.

The above-described procedure of coating the PZT precursor solution on lower electrode layer 4, drying, and thermal decomposition is repeated a plurality of times such that the thickness of the PZT precursor film becomes a predetermined value. Thereafter, the PZT precursor film is subjected to crystallization by using the RTA furnace. The crystallization treatment is carried out under conditions of a temperature of 550° C. for 5 minutes at a heating rate of 200° C./min. A preferable crystallization temperature range is 500° C. or higher and lower than 750° C. When the crystallization temperature is 750° C. or higher, Pb becomes short due to evaporation of Pb contained in the PZT precursor film, and the crystallinity is deteriorated. The above-mentioned procedure permits production of piezoelectric layer 6 formed of PZT that is highly oriented in a (001) plane direction or a (100) plane direction.

In the above description, in order to form piezoelectric layer 6 having a predetermined thickness, coating of the precursor solution and thermal decomposition are repeated a plurality of times, and then, the precursor film is subjected to crystallization. However, procedures from the coating of the precursor solution to crystallization may be repeated.

When piezoelectric layer 6 is formed by the CSD method, crystallization treatment is carried out at the time of film formation. Since PZT is crystallized at a high temperature, compressive stress remains due to a difference in the coefficient of thermal expansion between board 2 and piezoelectric layer 6 when the temperature drops to room temperature. For example, when SUS430 that is ferrite-based stainless steel standardized by JIS G4308 is used for board 2, the coefficient of thermal expansion of SUS430 is 105×10⁻⁷/° C. Note here that SUS430 corresponds to ISO number of 4016-430-00-I and mark of X6Cr17 in the International Standard ISO15510, and includes iron as a main component, and 16 to 18 wt. % of chromium. Since the coefficient of thermal expansion of PZT is 79×10⁻⁷/° C. and the coefficient of thermal expansion of SUS430 is larger than that of PZT, a compressive stress remains in the plane direction of piezoelectric layer 6.

Finally, upper electrode layer 7 is formed on piezoelectric layer 6 by an ion beam vapor deposition method using, for example, gold. A method for forming upper electrode layer 7 is not necessarily limited to the ion beam vapor deposition method. Examples of the method may include a resistance-heating vapor deposition method, a sputtering method, or the like.

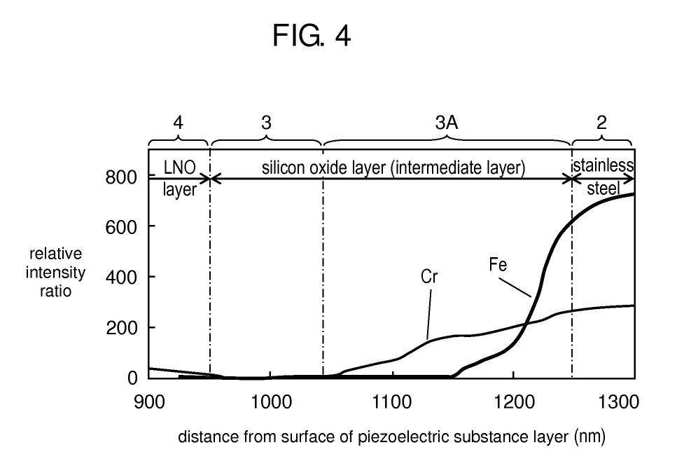

Herein, elemental analysis results in the laminating direction of piezoelectric element 1 are described with reference to FIG. 4. FIG. 4 is a graph showing elemental analysis results in the depth direction of piezoelectric element 1, and shows a concentration gradient of the metal elements diffusing from board 2 in the laminating direction of piezoelectric element 1.

As the elemental analysis, EDX (Energy Dispersive X-ray Spectrometry) is used, and iron and chromium are detected. FIG. 4 shows a graph formed by plotting a distance from the surface of piezoelectric layer 6 in a direction to board 2 in abscissa, and a relative strength ratio of each detection element in ordinate by using the measurement results.

FIG. 4 shows that a part near board 2 in the intermediate layer made of silicon oxide formed on the board 2 made of stainless steel includes iron and chromium diffusing from board 2. This part is diffusion layer 3A. Furthermore, it can be confirmed that as compared with iron, chromium diffuses to a region nearer to lower electrode layer 4 of the intermediate layer. Therefore, the coefficient of thermal expansion of the integrated layer composed of diffusion layer 3A and first isolation layer 3 becomes smaller from board 2 to lower electrode layer 4.

On the other hand, in a region including an interface between the intermediate layer and lower electrode layer 4, there is first isolation layer 3 that is free from iron and chromium. That is to say, by forming the intermediate layer on board 2, diffusion of iron and/or chromium into lower electrode layer 4 as a LNO layer and piezoelectric layer 6 composed of PZT is suppressed. Note here that energy values of characteristic X-rays of Cr and La are overlapped with each other. Therefore, Cr is observed to be detected in the LNO layer based on La as the constituent element of the LNO layer.

In FIG. 4, diffusion layer 3A includes a region near board 2, in which iron and chromium are included, and a region near first isolation layer 3, in which iron is not included and chromium is included. In this way, diffusion layer 3A may be composed of two types of regions (layers), or may be composed of a single layer including iron and chromium with a concentration gradient. Even in the former case, diffusion layer 3A as a whole includes iron and chromium.

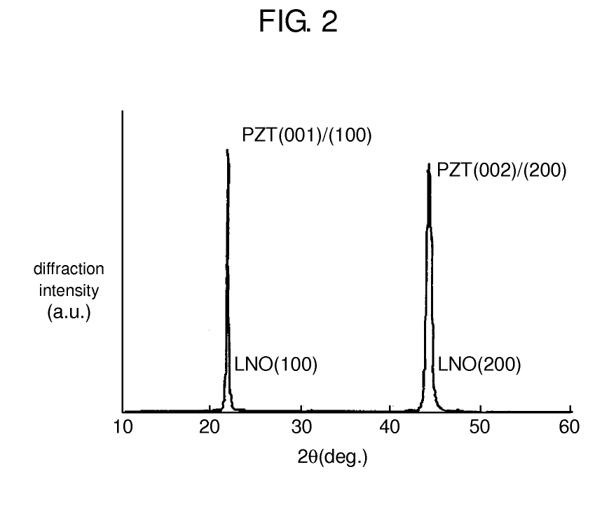

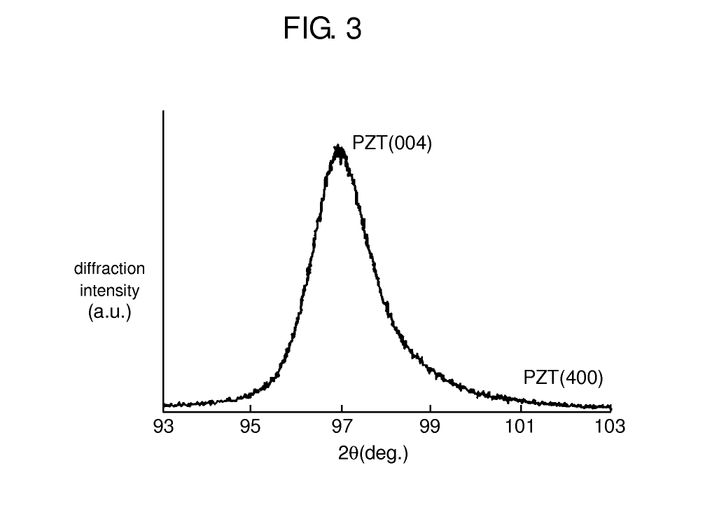

Next, results of evaluation of crystallinity of piezoelectric element 1 are shown in FIGS. 2 and 3. FIG. 2 is a graph showing an X-ray diffraction pattern of piezoelectric layer 6 in a range in which 2θ is 10° or more and 60° or less. Similarly, FIG. 3 is a graph showing a range in which 2θ is 93° or more and 103° or less.

FIG. 2 shows that piezoelectric layer 6 is selectively oriented only in the PZT (001)/(100) directions. Furthermore, FIG. 3 shows that a peak of the (004) plane and a peak of the (400) plane are separated from each other in piezoelectric layer 6, and that the peak of the (004) plane is larger than the (400) plane. Therefore, it is shown that PZT forming piezoelectric layer 6 is selectively oriented in the (004) direction that is a polarization axial direction.

Furthermore, Table 1 shows evaluation results of remanent polarization (hereinafter, referred to as Pᵣ) of piezoelectric element 1.

The polarization characteristic is known to be proportional to the piezoelectric property. It is generally known that the larger the polarization value is, the more excellent the piezoelectric property is. Pᵣ is measured by using a ferroelectric tester (Precision LC) manufactured by Radiant Technologies Inc. Note here that an applied voltage at the time of measurement is 70V, measurement frequency is 1 KHz, and a measurement temperature is room temperature. For comparison, Table 1 also shows a measurement result of a case in which a plate of Si whose coefficient of thermal expansion is smaller than PZT (coefficient of thermal expansion: 28×10⁻⁷/° C.) is used instead of board 2.

TABLE 1

| | SUS430 | Si |
|---|---|---|
| remanent | 28 | 18 |
| polarization Pᵣ | | |
| (μC/cm²) | | |

From Table 1, it is shown that the Pᵣ value is larger in piezoelectric element 1 using SUS430 for board 2 as compared with that of a piezoelectric element using Si for the board. From the above-mentioned results, it is shown that the polarization characteristic is improved by selectively orienting piezoelectric layer 6 in the (004) direction that is a polarization axial direction. For applying a compressive stress to piezoelectric layer 6, it is necessary that stress applied to piezoelectric layer 6 in a high temperature state at film formation is released. Therefore, when a vapor growth method such as a sputtering method is used for film formation of piezoelectric layer 6, it is necessary that the film is formed in an amorphous state without heating.

Next, results of evaluation of warpage of piezoelectric element 1 is described. The warpage of piezoelectric element 1 is evaluated by a radius of curvature R of board 2. A larger radius of curvature means that the warpage is small. On the contrary, a smaller radius of curvature means that the warpage is large.

Table 2 shows measurement results of the radius of curvature of piezoelectric element 1. For comparison, Table 2 also shows measurement results of piezoelectric elements in which the intermediate layer is formed of titanium oxide or hafnium oxide are also shown together in Table 2.

TABLE 2

| | silicon oxide | titanium oxide | hafnium oxide |
|---|---|---|---|
| radius of | 1.1 × 10¹⁰ | 2.8 × 10⁹ | 4.4 × 10⁹ |
| curvature | | | |
| (nm) | | | |

From Table 2, it is shown that the value of the radius of curvature of piezoelectric element 1 in which the intermediate layer is formed of silicon oxide is larger than that of the piezoelectric elements in which the intermediate layer is formed of titanium oxide or hafnium oxide. That is to say, when the intermediate layer is formed of silicon oxide, warpage of board 2 can be reduced. As mentioned above, iron or chromium diffuses from board 2 to the intermediate layer formed of silicon oxide, and thus, diffusion layer 3A is formed. Therefore, a thermal stress from board 2 is relaxed. On the other hand, iron or chromium does not easily diffuse to the intermediate layer formed of titanium oxide or hafnium oxide. As a result, results shown in Table 2 are obtained.

As mentioned above, when diffusion layer 3A and first isolation layer 3 are sequentially formed on board 2 as mentioned above, it is possible to produce dielectric element substrate 5 in which warpage of board 2 during film formation process is reduced.

### Second Exemplary Embodiment

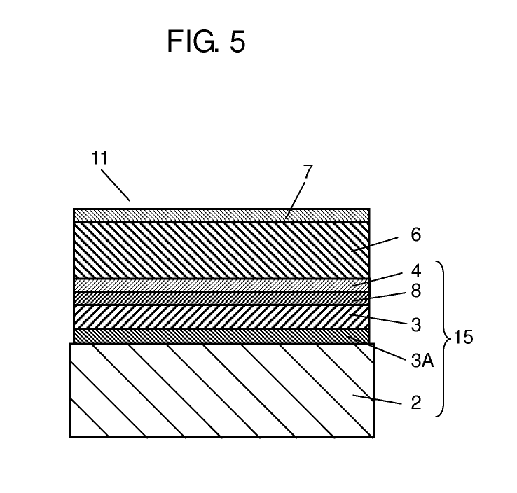

FIG. 5 is a sectional view showing one structural example of a piezoelectric element in accordance with a second exemplary embodiment of the present invention. Dielectric element substrate 15 of piezoelectric element 11 has the same structure as that of dielectric element substrate 5 piezoelectric element 1 described in the first exemplary embodiment except that electric element substrate 15 includes second isolation layer 8 between first isolation layer 3 and lower electrode layer 4 in piezoelectric element 11.

Second isolation layer 8 has a larger coefficient of thermal expansion than that of first isolation layer 3, and is formed of material that suppresses diffusion of iron and chromium that are constituent elements of board 2. In the following description, second isolation layer 8 is formed of hafnium oxide. However, the material is not necessarily limited to hafnium oxide as long as the material has a larger coefficient of thermal expansion than that of first isolation layer 3, and has a function for suppressing diffusion of iron and chromium that are constituent elements of board 2. Examples of the material include titanium, aluminum, and magnesium oxides, and oxides including thereof as a main component.

Hereinafter, one example of a method for forming second isolation layer 8 formed of hafnium oxide is described. Firstly, hafnium alkoxide is dissolved in isopentyl acetate to prepare a hafnium oxide precursor solution. As the hafnium alkoxide, hafnium tetramethoxide (Hf(OCH₃)₄), hafnium tetraisopropoxide (Hf[OCH(CH₃)₂]₄), or the like, may be used. Then, for forming hafnium oxide as second isolation layer 8 on first isolation layer 3, the hafnium oxide precursor solution is coated by spin coating. The spin coating of the hafnium oxide precursor solution on first isolation layer 3 is carried out under the conditions of a rotational speed of 2500 rpm for 30 seconds.

Thereafter, the coated film is dried by heating at 150° C. for 10 minutes. The drying conditions are the same as those for the coated film when the intermediate layer is formed. That is to say, it is desirable that the drying temperature is higher than 100° C. and lower than 200° C. Thereafter, heating is carried out at 550° C. for 10 minutes, and thereby the residual organic substance is thermally decomposed so as to increase the density of the film.

A series of operations including coating the precursor solution on first isolation layer 3, drying thereof and increasing the density, is repeated a plurality of times so that a predetermined thickness is obtained, thus forming second isolation layer 8. Note here that second isolation layer 8 formed of hafnium oxide may be formed by various well-known film formation methods including vapor growth methods such as a sputtering method, a CVD method, or the like.

Table 3 shows values of remanent polarization Pᵣ in the first and second exemplary embodiments together.

TABLE 3

| | including hafnium | excluding hafnium |
|---|---|---|
| | oxide layer (second | oxide layer (first |
| | exemplary | exemplary |
| | embodiment) | embodiment) |
| remanent polarization | 35 | 28 |
| Pᵣ (μC/cm²) | | |

In piezoelectric element 11, second isolation layer 8 formed of hafnium oxide is inserted between first isolation layer 3 formed of silicon oxide and lower electrode layer 4 formed of LNO. In this configuration, the coefficient of thermal expansion of second isolation layer 8 is larger than the coefficient of thermal expansion of first isolation layer 3. Therefore, as compared with piezoelectric element excluding second isolation layer 8 in the first exemplary embodiment, a larger compressive stress is applied to piezoelectric layer 6, and the crystal orientation of piezoelectric layer 6 is improved. As a result, as shown in Table 3, the Pᵣ value of piezoelectric element 11 is larger than that of piezoelectric element 1.

As described above, when second isolation layer 8 is provided between first isolation layer 3 and lower electrode layer 4, a larger compressive stress can be applied to piezoelectric layer 6, and piezoelectric elements having more excellent polarization characteristics can be produced.

### INDUSTRIAL APPLICABILITY

According to the present invention, it is possible to produce a piezoelectric element in which warpage of a substrate is suppressed and which includes a piezoelectric layer having high polarization characteristics. The piezoelectric element is useful for various sensors such as an angular velocity sensor, various actuators such as a piezoelectric actuator and an ultrasonic wave motor, and optical devices such as an optical scanner and an optical switch, which are used for various electronic apparatuses.

1. A dielectric element substrate comprising:
a board including a first metal element and a second metal element;
a diffusion layer provided on the board;
a first isolation layer provided on and unitarily with the diffusion layer; and
a lower electrode layer provided on the first isolation layer at an opposite side with respect to the diffusion layer so as to be isolated from the diffusion layer by the first isolation layer,
wherein the diffusion layer is formed by allowing the first metal element and the second metal element to diffuse from the board to same material as that of the first isolation layer,
the first isolation layer is free from the first metal element and the second metal element, and
a coefficient of thermal expansion of the diffusion layer monotonously decreases from the board to the first isolation layer.

2. The dielectric element substrate according to claim 1, wherein a concentration gradient of the first metal element and a concentration gradient of the second metal element of the diffusion layer are different from each other in a direction from the board to the first isolation layer.

3. The dielectric element substrate according to claim 1, wherein the first metal element is iron, and the second metal element is chromium.

4. The dielectric element substrate according to claim 3, wherein a diffusion length of chromium is larger than a diffusion length of iron in a direction from the board to the first isolation layer.

5. The dielectric element substrate according to claim 1, wherein the first isolation layer is formed of silicon oxide.

6. The dielectric element substrate according to claim 1, further comprising a second isolation layer provided between the first isolation layer and the lower electrode layer, having a coefficient of thermal expansion larger than that of the first isolation layer, and having smaller diffusion of the first metal element and the second metal element than that in the first isolation layer.

7. A method for producing a dielectric element substrate, the method comprising:
forming an intermediate layer on a board including a first metal element and a second metal element;
forming a diffusion layer adjacent to the board in the intermediate layer by allowing the first metal element and the second metal element to diffuse from the board, and forming a first isolation layer, which is free from the first metal element and the second metal element, at an opposite side to the board of the intermediate layer; and
forming a lower electrode layer on the first isolation layer at an opposite side to the diffusion layer,
wherein the diffusion layer is formed in such a manner that a coefficient of thermal expansion of the diffusion layer monotonously decreases from the board to the first isolation layer.

8. The method for producing a dielectric element substrate according to claim 7, wherein the diffusion layer is formed in such a manner that a concentration gradient of the first metal element and a concentration gradient of the second metal element are different from each other in a direction from the board to the first isolation layer.

9. The method for producing a dielectric element substrate according to claim 7, wherein when the intermediate layer is formed, a precursor solution for forming the intermediate layer is applied on the board, thus forming a precursor film; and
when the diffusion layer is formed, the precursor film is crystallized by heating and cooling, and the first metal element and the second metal element are diffused from the board to the precursor film.

10. The method for producing a dielectric element substrate according to claim 7, wherein the first metal element is iron, and the second metal element is chromium.

11. A piezoelectric element comprising:
the dielectric element substrate as defined in claim 1;
a piezoelectric layer provided on the lower electrode layer of the dielectric element substrate; and
an upper electrode layer provided on the piezoelectric layer.

12. The piezoelectric element according to claim 11, wherein a coefficient of thermal expansion of the board is larger than a coefficient of thermal expansion of the piezoelectric layer.
